(19) United States
(12) Patent Application Publication
(10) Pub. No.: US 2007/0181897 A1
(43) Pub. Date: Aug. 9, 2007

(54) High heat dissipating package baseplate for a high brightness LED

(76) Inventor: Been-Yu Liaw, Jhongli City (TW)

Correspondence Address: Troxell Law Office Pllc, Suite 1404, 5205 Leesburg Pike, Falls Church, VA, 22041, US

(21) Appl. No.: 11/346,359

(22) Filed: Feb. 3, 2006

(51) Int. Cl. H01L 33/00

(52) U.S. Cl. 257/99

(57) ABSTRACT

A high heat dissipating package baseplate for a high brightness LED, wherein a package baseplate manufacturing process includes a baseplate manufacturing process, a wiring manufacturing process and a package manufacturing process. An arc concavity is formed in a surface of a heat dissipating piece, and a light reflecting layer having light gathering effectiveness is made to cover a surface of the concavity. A light-emitting diode is disposed on the light reflecting layer, a printed circuit board is disposed on the heat dissipating piece, making a package baseplate finished product. The heat from the light-emitting diode is directly conducted away through the heat dissipating piece serving as a thermal conducting medium, thereby shortening the path that heat dissipation must pass through, which increases speed and improves effectiveness of heat dissipation. Moreover, such a configuration is dissimilar to any cup-shaped attachment method of prior art used as a thermal conduction means.

### BACKGROUND OF THE INVENTION

(a) Field of the Invention

The present invention relates to a high heat dissipating package baseplate for a high brightness LED (light-emitting diode).

(b) Description of the Prior Art

Referring to FIGS. 1 and 2, which show a prior art package baseplate A, wherein a light condensing cup A1 that is used to gather light is first manufactured, then a light-emitting diode A2 is disposed within the light condensing cup Al, which is then attached to a printed circuit board A3 for electrical connection thereto, and the printed circuit board A3 is attached to a heat dissipating piece A4, thereby completing the package baseplate A finished product. When the light-emitting diode A2 is consuming power and producing heat, the heat produced must be indirectly conducted through the light condensing cup A1 and the printed circuit board A3, before it is finally conducted to the heat dissipating piece A4, where it is dissipated. Accordingly, the number of mediums that the heat must pass through is inordinate and thermal resistance is excessively high, resulting in an excessively long heat dissipating path, which slows the speed of heat dissipation and brings about ineffective cooling. Hence, the heat produced by the light-emitting diode A2 is unable to be effectively conducted away, thereby reducing the serviceable life and weakening brightness of the light-emitting diode A2. Furthermore, because the light condensing cup A1, which is used to gather light from the light-emitting diode A2, must be first manufactured, thus, manufacturing cost of the package baseplate A is accordingly increased.

### SUMMARY OF THE INVENTION

The present invention provides a high heat dissipating package baseplate for a high brightness LED (light-emitting diode), and more particularly to a package baseplate manufacturing process that achieves effective light gathering, low thermal resistance and rapid heat dissipation. Moreover, the present invention is able to heighten brightness and increase serviceable life of a light-emitting diode.

To enable a further understanding of said objectives and the technological methods of the invention herein, brief description of the drawings is provided below followed by detailed description of the preferred embodiments.

### BRIEF DESCRIPTION OF THE DRAWINGS

FIG. 1 shows an elevational view of prior art.

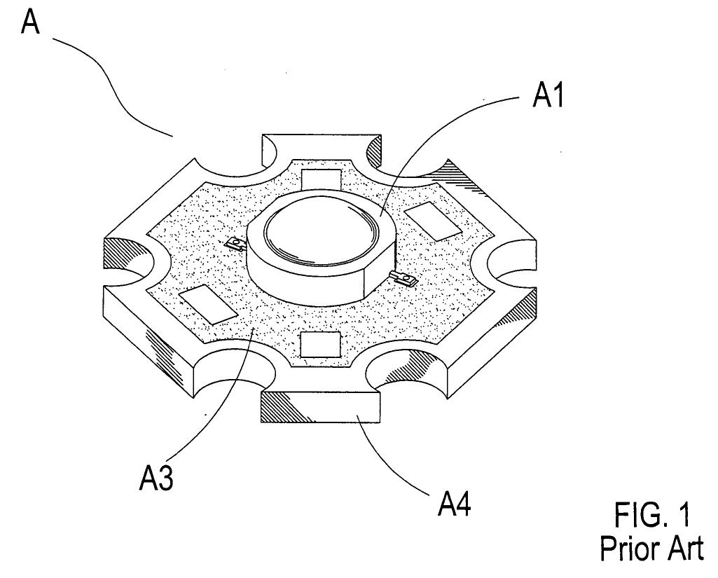

FIG. 2 shows a cutaway view of prior art.

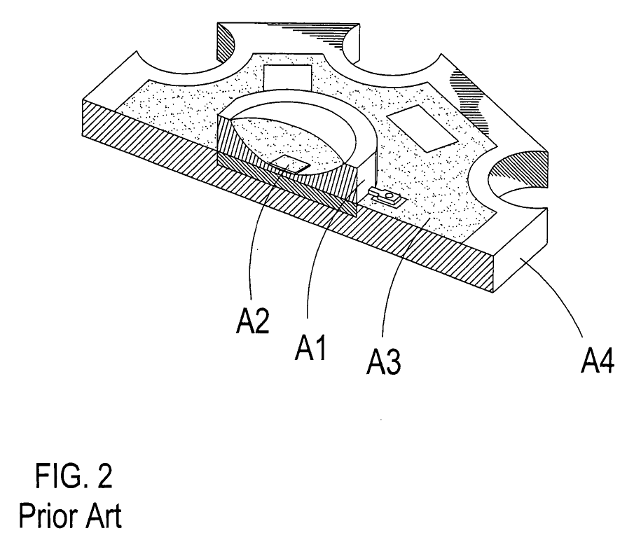

FIG. 3 shows a block diagram according to the present invention.

FIG. 4 shows a flow chart according to the present invention.

FIG. 5 shows a cutaway elevational view of the present invention.

FIG. 6 shows a first view of an embodiment according to the present invention.

FIG. 7 shows a second view of the embodiment according to the present invention.

FIG. 8 shows a third view of the embodiment according to the present invention.

### DETAILED DESCRIPTION OF THE PREFERRED EMBODIMENTS

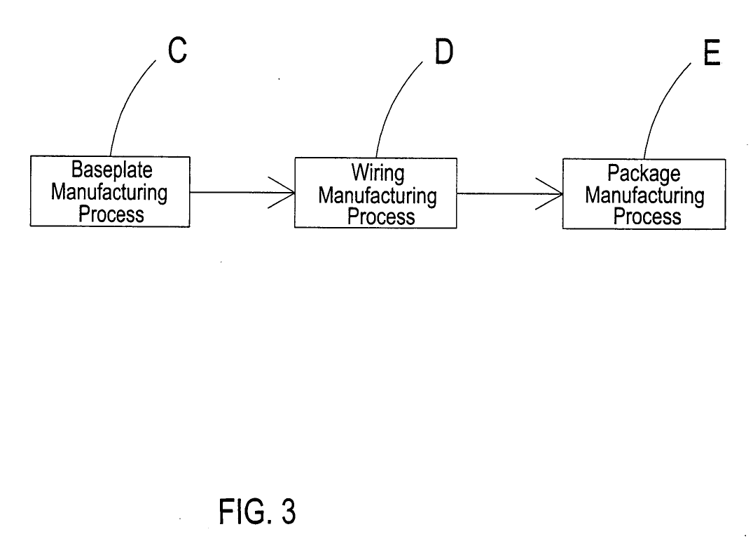

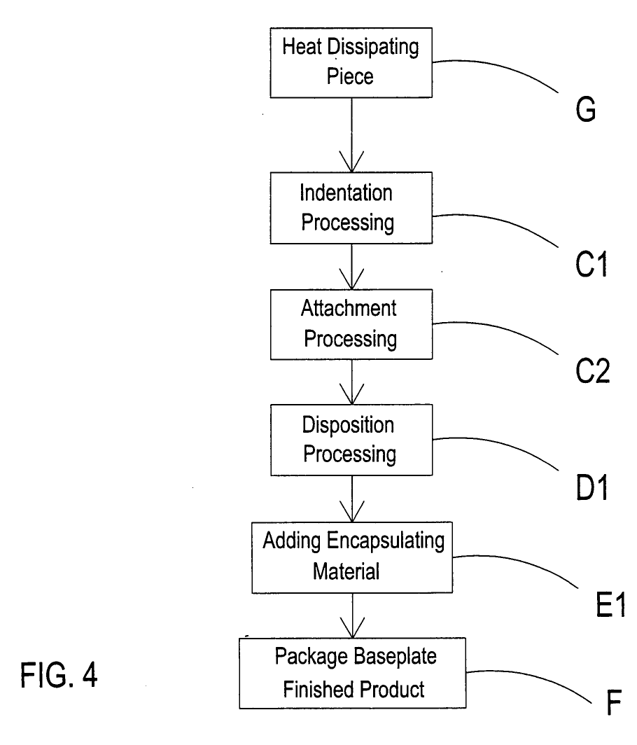

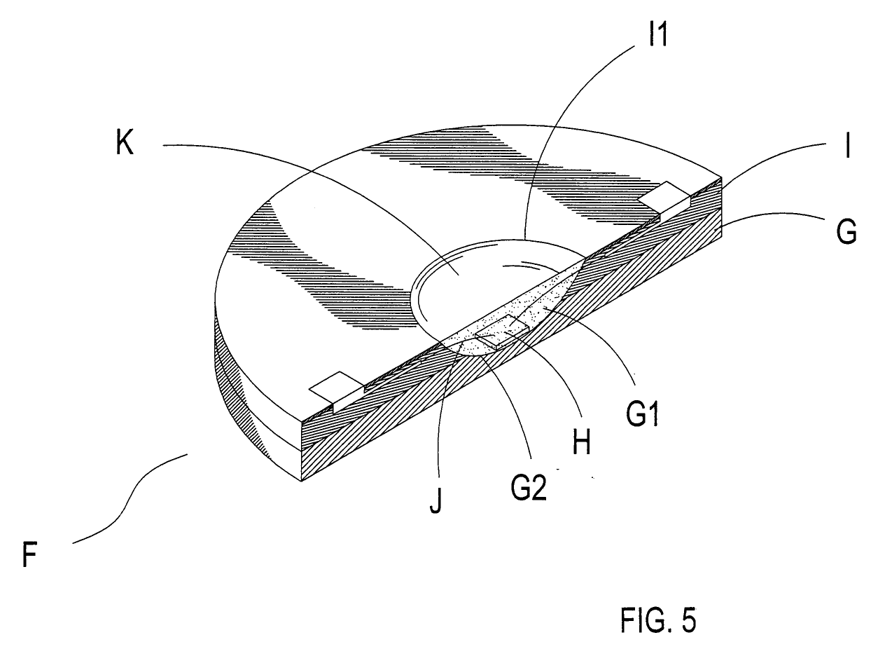

The present invention provides a high heat dissipating package baseplate for a high brightness LED (light-emitting diode). Referring to FIGS. 3, 4 and 5, a package baseplate manufacturing process B comprises at least a baseplate manufacturing process C, a wiring manufacturing process D and a package manufacturing process E, wherein the baseplate manufacturing process C includes implementing indentation processing C1 of a heat dissipating piece G, which forms an arc concavity G1 in a surface of the heat dissipating piece G, then attachment processing C2 is carried out to cover a surface of the concavity G1 with a light reflecting layer G2 having light gathering effectiveness. The wiring manufacturing process D includes implementing disposition processing D1 on the heat dissipating piece G whereby a light-emitting diode H is disposed on the light reflecting layer G2, and a printed circuit board I is disposed on the heat dissipating piece G. The printed circuit board I is provided with a through hole I1 corresponding to position of the concavity G1, and disposition of a plurality of lead wires J that provide electrical connections between the light-emitting diode H and the printed circuit board I. Furthermore, the package manufacturing process E includes a process involving adding encapsulating material E1 into the concavity G1, whereby an encapsulating compound K is used to cover the light reflecting layer G2, the light-emitting diode H and the plurality of lead wires J. Moreover, the encapsulating compound K fills the through hole I1 of the printed circuit board I, thereby acquiring a package baseplate finished product F.

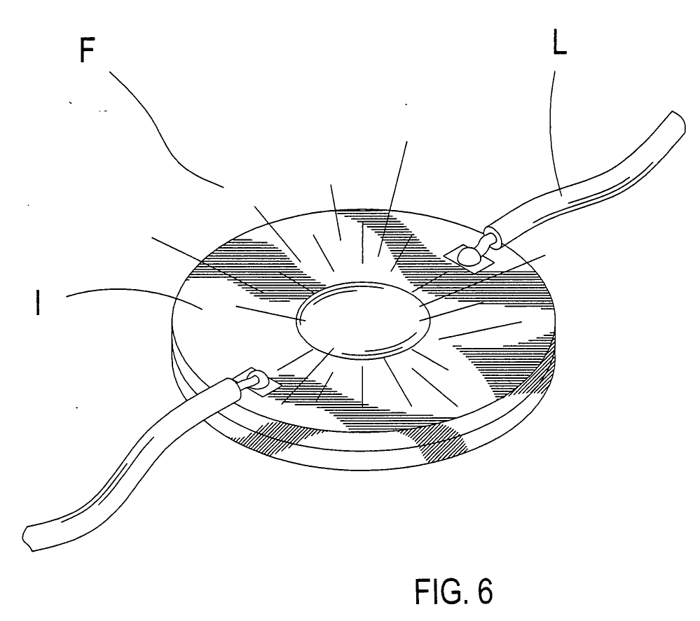

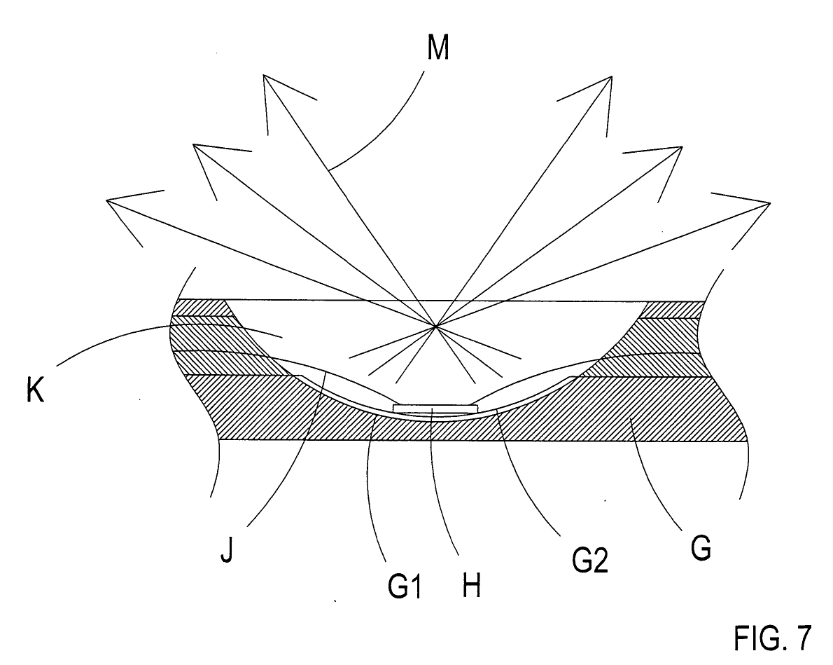

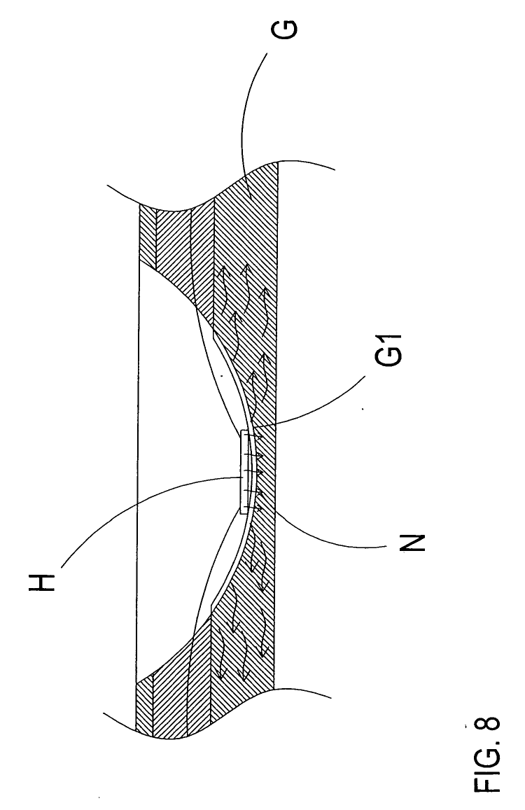

Referring to FIGS. 6, 7 and 8, which show an embodiment of the present invention comprising the high heat dissipating package baseplate for a high brightness LED (light-emitting diode), wherein a power source L is connected to the package baseplate finished product F. The current supplied by the power source L is transmitted to the light-emitting diode H through the plurality of lead wires J on the printed circuit board I, thereby electrically connecting the light-emitting diode H and enabling it to emit a light source M. The arc-shape and the light reflecting layer G2 covering the surface of the concavity G1 of the heat dissipating piece G gathers the light source M and emits it out from the encapsulating compound K. When the light-emitting diode H is electrically connected and emitting the light source M, the light-emitting diode H consumes power and generates a heat source N. Because the light-emitting diode H in the package baseplate manufacturing process B (see FIG. 3) is directly disposed within the concavity G1 of the heat dissipating piece G, thus, the heat source N is directly conducted away by the heat dissipating piece G serving as a thermal conducting medium, thereby shortening the path that the heat source N must pass through, which increases speed and improves effectiveness of heat dissipation. Moreover, such a configuration is dissimilar to any cup-shaped attachment method of prior art used as a thermal conduction means.

The high heat dissipating characteristic of the package baseplate finished product F and rapid and effective heat dissipation implemented by the heat dissipating piece G enable the light-emitting diode H to carry on operating under overfrequency conditions, thereby enabling the light-emitting diode H to operate normally under conditions when the luminous power exceeds several times the original, normal luminous power to produce the light source M having even greater brightness.

In order to better explicitly disclose advancement and practicability of the present invention, advantages of the present invention are enumerated particularized hereinafter:

1. The concavity G1 directly defined on the heat dissipating piece G has light gathering functionality.

2. Shortens the path heat dissipation must pass through.

3. Speed of heat dissipation is rapid and superior.

4. Reduces costs.

5. Enables the light-emitting diode H to operate under higher power consumption and emit the light source M having relatively brighter primary colors, thereby achieving brightness that prior art is unable to achieve, moreover, achieves the objective of operating under overfrequency conditions.

6. Provided with commercial competitiveness.

7. Provided with commercial utility value.

8. Provided with originality.

In conclusion, the present invention complies with essential elements as required for a new patent application, in accordance with which a new patent application is proposed herein.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A high heat dissipating package baseplate for a high brightness LED, wherein a package baseplate manufacturing process comprises:
a baseplate manufacturing process, wherein an arc concavity is formed in a surface of a heat dissipating piece, and a surface of the concavity is covered with a light reflecting layer having light gathering effectiveness;
a wiring manufacturing process, wherein a light-emitting diode is disposed on the light reflecting layer, and a printed circuit board is disposed on the heat dissipating piece, moreover, a plurality of lead wires provide electrical connections between the light-emitting diode and the printed circuit board; the printed circuit board is provided with a through hole corresponding to position of the concavity; and
a package manufacturing process, wherein an encapsulating compound is added to the light reflecting layer and fills the concavity and the through hole, thus, the encapsulating compound covers the light-emitting diode and the plurality of lead wires.

2. The high heat dissipating package baseplate for a high brightness LED according to claim 1, wherein the heat dissipating piece is fabricated from copper material, aluminum material, alloy material, ceramic material and related material having high heat dissipating effect.

3. The high heat dissipating package baseplate for a high brightness LED according to claim 1, wherein the concavity is formed using methods including a CNC (Computer Numerical Control) lathe, a punching machine, electroforming, laser, electrodischarge machining, ejection forming and related methods able to form an arc indentation on the heat dissipating piece.

4. The high heat dissipating package baseplate for a high brightness LED according to claim 1, wherein the reflecting layer is formed from material including silver-plate, industrial silver luster and related material having light reflecting properties.

5. The high heat dissipating package baseplate for a high brightness LED according to claim 1, wherein the encapsulating compound is epoxy resin and related material having light transmitting properties.
